(19) United States
(12) Patent Application Publication
(10) Pub. No.: US 2025/0089330 A1
(43) Pub. Date: Mar. 13, 2025

(54) SELECTIVE DEPOSITION OF MASK FOR REDUCING NANO SHEET LOSS

(71) Applicant: Taiwan Semiconductor Manufacturing Co., Ltd., Hsinchu (TW)

(72) Inventors: Cheng-Yu Wei, Taoyuan City (TW); Cheng-I Lin, Hsinchu (TW); Hao-Ming Tang, Taipei City (TW); Shu-Han Chen, Hsinchu (TW); Chi On Chui, Hsinchu (TW)

(21) Appl. No.: 18/516,147

(22) Filed: Nov. 21, 2023

Related U.S. Application Data
(60) Provisional application No. 63/581,043, filed on Sep. 7, 2023.

(51) Int. Cl. H01L 29/66; H01L 21/8234; H01L 27/088; H01L 29/06; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 64/021; H10D 84/0135; H10D 84/0147; H10D 84/038; H10D 84/83

(57) ABSTRACT

A method includes forming a protruding fin, and forming a first dielectric layer including a first dielectric layer and a second dielectric layer over the first dielectric layer. The first dielectric layer includes a first top portion on a top surface of the protruding fin, and a sidewall portion on a sidewall of the protruding fin. The second dielectric layer is over the first top portion and the top surface of the protruding fin, and is formed using an anisotropic deposition process. The method further includes forming a dummy gate electrode on the second dielectric layer, forming a gate spacer on a sidewall of the dummy gate electrode, removing the dummy gate electrode, and forming a replacement gate electrode in a space left by the dummy gate electrode.

### PRIORITY CLAIM AND CROSS-REFERENCE

This application claims the benefit of the following provisionally filed U.S. Patent application: Application No. 63/581,043, filed on Sep. 7, 2023, and entitled “SELECTIVITY ANISOTROPIC DEPOSITION OF ALTERNATIVE DIELECTRIC METHODS FOR NANOSHEET LOSS AND STI OXIDE PROTECTION,” which application is hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-3, 4A, 4B, 5, 6A, 6B, 6C, 7, 8A, 8B, 8C, 9A, 9B, 10A, 10B, 11A, 11B, 11C, 12A, 12B, 13A, 13B, 14A, 14B, 15A, 15B, 15C, and 15D illustrate the view of intermediate stages in the formation of a Gate All-Around (GAA) transistor in accordance with some embodiments.

FIG. 16 illustrates a process flow for forming a GAA transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate-All-Around (GAA) transistor with reduced loss in top semiconductor nanostructure and reduced loss in Shallow Trench Isolation (STI) region, and the respective methods are provided. In accordance with some embodiments, a first dielectric layer is formed on a protruding fin using a conformal deposition process. A second dielectric layer is formed on the first dielectric layer using an anisotropic deposition process. The second dielectric layer is used as a hard mask, and is on the top surface, but may not be on the sidewalls, of the protruding fin. The second dielectric layer thus may be formed with the top portion being thicker to provide better protection without occupying the space between neighboring protruding fins. It is appreciated that although GAA transistors are used as examples, other types of transistors such as Fin Field-Effect Transistors (FinFETs) may also adopt the embodiments of the present disclosure.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

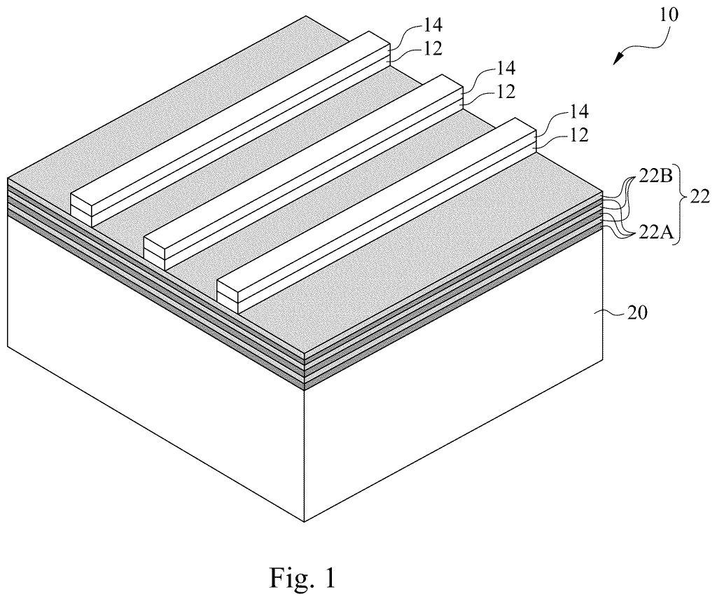

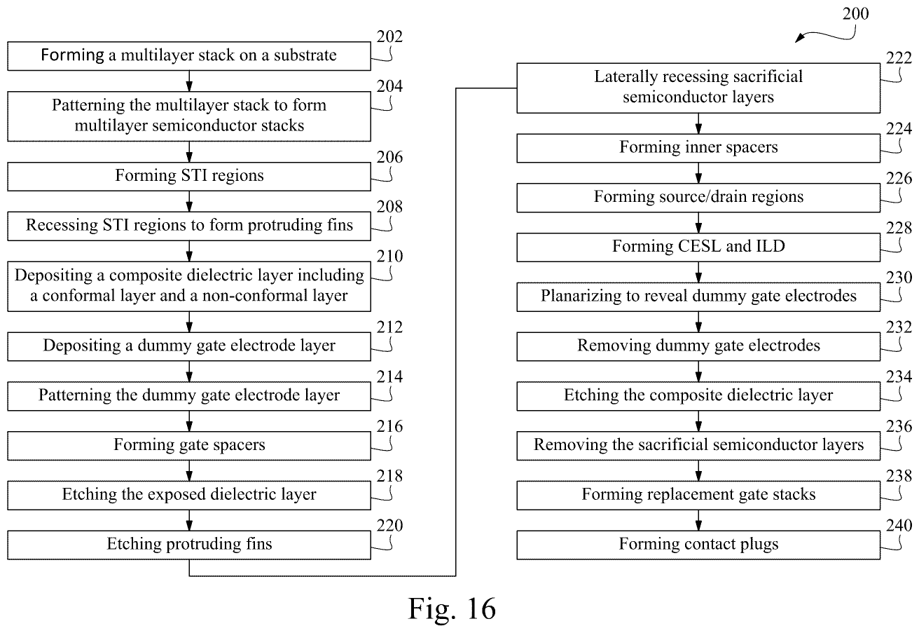

FIGS. 1-3, 4A, 4B, 5, 6A, 6B, 6C, 7, 8A, 8B, 8C, 9A, 9B, 10A, 10B, 11A, 11B, 11C, 12A, 12B, 13A, 13B, 14A, 14B, 15A, 15B, 15C, and 15D illustrate the views of f intermediate stages in the formation of a GAA transistor in accordance with some embodiments. The corresponding processes are also reflected schematically in the process flow shown in FIG. 16.

Referring to FIG. 1, a perspective view of wafer 10 is shown, which includes substrate 20. A multilayer structure comprising multilayer stack 22 is formed on substrate 20. In accordance with some embodiments, substrate 20 is or comprises a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of epitaxy processes for depositing alternating materials. The respective process is illustrated as process 202 in the process flow 200 as shown in FIG. 16. In accordance with some embodiments, multilayer stack 22 comprises first layers 22A formed of a first semiconductor material and second layers 22B formed of a second semiconductor material different from the first semiconductor material. Due to the epitaxy, the first layers 22A and the second layers 22B have the same lattice orientations as substrate 20.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A. For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A.

In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, pad oxide layer 12 and hard mask layer 14 are formed over multilayer stack 22. Pad oxide layer 12 may comprise silicon oxide, silicon carbide, or the like, while hard mask layer 14 may comprise silicon nitride, and other materials may be used. Pad oxide layer 12 and hard mask layer 14 are patterned to form a plurality of elongated strips, which are also referred to as pad oxides and hard masks.

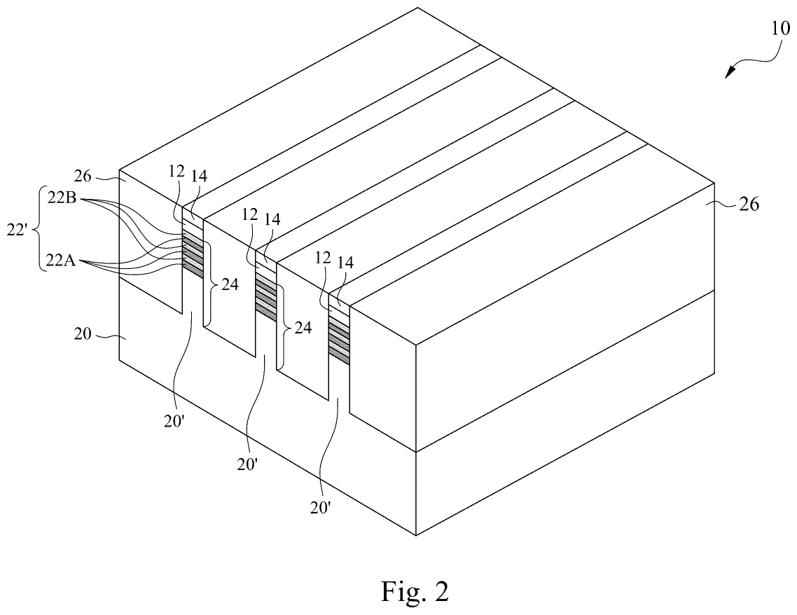

Referring to FIG. 2, multilayer stack 22 and a portion of the underlying substrate 20 are patterned in an etching process(es), so that trenches (filled with isolation regions 26) are formed. The trenches extend into substrate 20. The remaining portions of multilayer stacks are referred to as multilayer stacks 22′ hereinafter. The respective process is illustrated as process 204 in the process flow 200 as shown in FIG. 16. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Next, isolation regions 26 are formed, which may also be referred to as Shallow Trench Isolation (STI) regions throughout the description. The respective process is illustrated as process 206 in the process flow 200 as shown in FIG. 16. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, for example, with the top surface of hard mask layer 14, and the remaining portions of the dielectric material are STI regions 26.

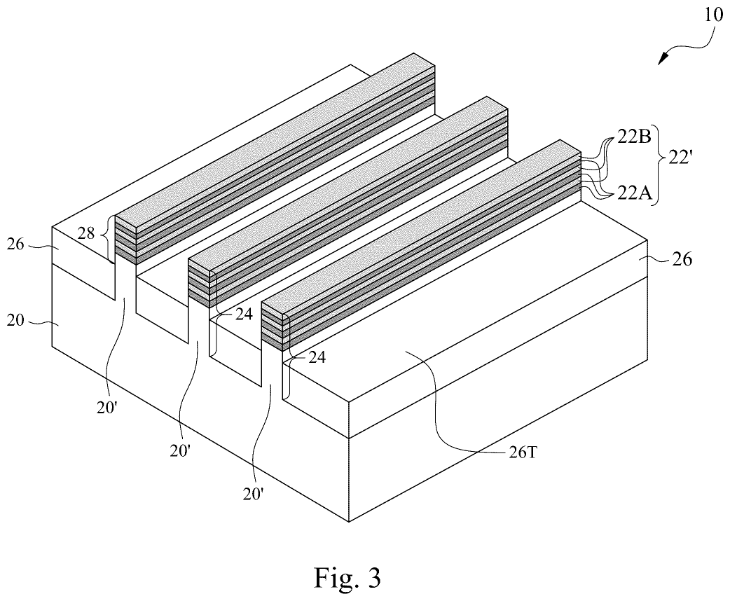

Further referring to FIG. 3, STI regions 26 are recessed, so that the top portions of semiconductor strips 24 protrude higher than the top surfaces 26T of the remaining portions of STI regions 26 to form protruding fins (structures) 28. The respective process is illustrated as process 208 in the process flow 200 as shown in FIG. 16. Protruding fins 28 include multilayer stacks 22′ and some top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example. Pad oxide layers 12 and hard masks 14 are removed.

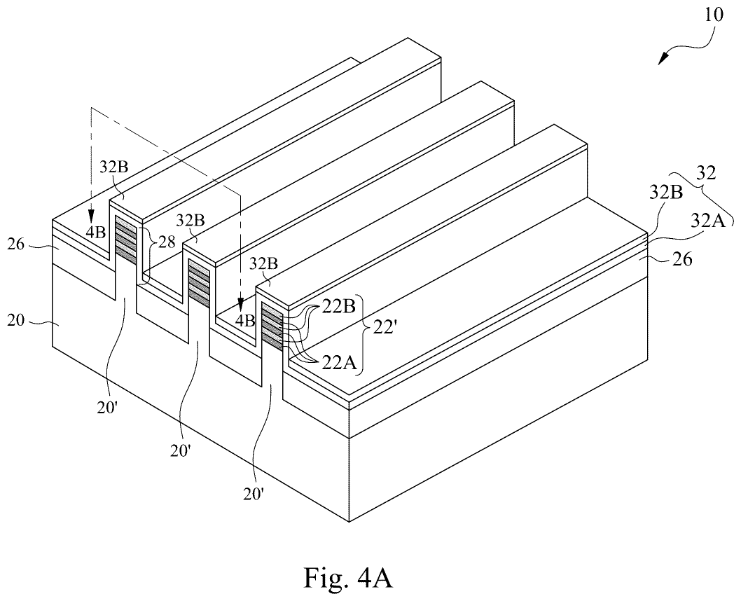

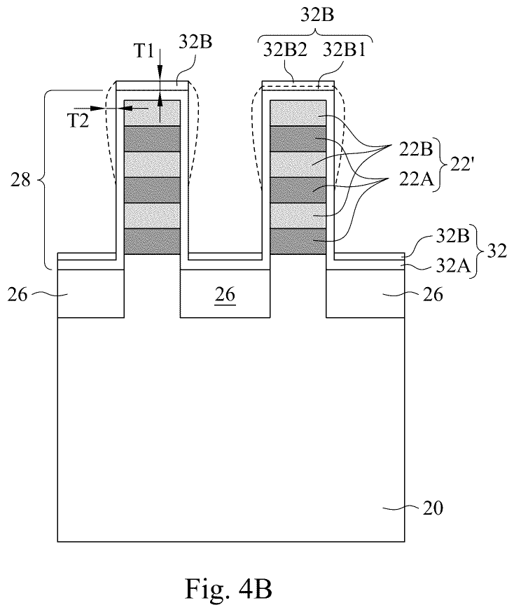

Referring to FIGS. 4A and 4B, composite dielectric layer 32, which includes dielectric layer 32A and dielectric layer 32B, is formed. The respective process is illustrated as process 210 in the process flow 200 as shown in FIG. 16. Dielectric layer 32A is deposited on the sidewalls and the top surfaces of protruding fins 28, and on the top surfaces of STI regions 26. FIG. 4A illustrates a perspective view, and FIG. 4B illustrates the vertical cross-section 4B-4B as shown in FIG. 4A.

In accordance with some embodiments, dielectric layer 32A is a single (homogeneous) layer, with an entirety of dielectric layer 32A being formed of a same material and having a same composition. Throughout the description, when two layers are referred to as having the same composition, it indicates that the two layers have same elements, and the percentages of the corresponding elements in two layers are the same as each other. Conversely, when two layers are referred to as having different compositions, it indicates that at least one of the two layers either has at least one element not in the other layer, or the two layers have the same elements, but the percentages of the elements in two layers are different from each other. In accordance with alternative embodiments, dielectric layer 32A is a composite layer including two or more sub layers.

In accordance with some embodiments, dielectric layer 32A is formed using a conformal deposition process, so that the vertical portions (also referred to as sidewall portions) and horizontal portions (also referred to as top portions) of dielectric layer 32A have a same thickness, for example, with a variation smaller than about 20 percent, smaller than about 10 percent, or lower. The formation is performed through a conformal formation process such as ALD, CVD, or the like. The materials of dielectric layer 32A may include an oxide such as silicon oxide, silicon oxynitride, silicon oxycarbide, or the like.

Dielectric layer 32B is then deposited on dielectric layer 32A using a non-conformal deposition process, which is also referred to as an anisotropic deposition process. Dielectric layers 32A and 32B are collectively referred to as composite dielectric layers 32 hereinafter. Dielectric layer 32B is also referred to as a hard mask layer since it prevents the undesirable etching in subsequent dummy gate patterning and cleaning processes. As shown in FIGS. 4A and 4B, dielectric layer 32B may include horizontal portions over the top surface of protruding fins 28 and STI regions 26. Dielectric layer 32B may be free, or substantially free, from vertical portions on sidewalls of protruding fins 28.

In accordance with alternative embodiments, dielectric layer 32B may include vertical portions on the sidewalls of protruding fins 28. The thickness T2 of the vertical portions, however, is significantly smaller than the thickness T1 of the horizontal portions. For example, the ratio T2/T1 may be smaller than about 0.2 or smaller than about 0.1.

FIG. 4B illustrates some example vertical portions of dielectric layer 32B. In accordance with some embodiments, the sidewalls of the top portions of protruding fins 28 have dielectric layer 32B thereon. The sidewalls of the bottom portions of protruding fins 28 do not have dielectric layer 32B thereon, and the corresponding bottom parts of dielectric layer 32A is exposed. In accordance with alternative embodiments, the vertical portions of dielectric layer 32B cover all of the sidewall portions of dielectric layer 32A, with thickness T2 being smaller than thickness T1.

Since the deposition of dielectric layer 32B is anisotropic, thinner or no vertical portions of the dielectric layer 32B will be formed between the closely located protruding fins 28 to cause the reduction of process window.

In accordance with some embodiments, dielectric layer 32B may be formed of a material different from that of dielectric layer 32A. For example, dielectric layer 32A may be formed of or comprise SiC, SiCN, SiN, SiO, SiOCN, SiON, or the like, or combinations thereof. It is noted that the value ranges are examples, and may be different than provided herein.

In accordance with alternative embodiments, dielectric layers 32A and 32B have the same elements such as Si, O, and N, or Si, O, C, and N, but have different percentages of the corresponding elements as deposited, and/or after subsequent thermal processes. For example, the atomic percentages of C and/or N in dielectric layer 32B may be higher than that of dielectric layer 32A, and the atomic percentage of O in dielectric layer 32A may be higher than that of dielectric layer 32B.

In accordance with yet alternative embodiments, dielectric layer 32B is a composite layer including a lower sub layer and an upper sub layer (referred to as sub layers 32B1 and 32B2, not shown). Sub layers 32B1 and 32B2 are illustrated for one dielectric layer 32B, while they may be in each of the illustrated portions of dielectric layer 32B. Each of sub layers 32B1 and 32B2 may be formed of or comprise a dielectric material different from the dielectric material of dielectric layer 32A. While the material of sub layers 32B1 and 32B2 are different from each other, each of sub layers 32B1 and 32B2 may be formed of the material (as aforementioned) that has the lower etching rate than that of dielectric layer 32A in the subsequent patterning and cleaning of dummy gate electrodes 34. For example, each of the sub layers 32B1 and 32B2 may be selected from the same group of candidate materials, which may include SiC, SiOC, SiON, SiCN, SiN, SiOCN, or the like.

In accordance with yet alternative embodiments in which dielectric layer 32B is a composite layer, each of sub layers 32B1 and 32B2 may have a uniform composition. When dielectric layer 32B is a single layer, the entirety of dielectric layer 32B may be deposited as having a uniform composite. In accordance with alternative embodiments, dielectric layer 32B has a gradually changed composition, with different parts including the same elements (such as silicon, oxygen, and nitrogen), while from bottom to top, the percentage of the elements are gradually changed. For example, the bottom portion of dielectric layer 32B may comprise SiOx, while the top portion may include SiAE_{y}(or SiOAE_{y}) wherein “AE” represents an alternative element(s) such as C and/or N. From the bottom of dielectric layer 32B to the top of dielectric layer 32B, the atomic percentages y of element AE increase gradually. This may be achieved, for example, by gradually changing the flow rates of precursors when CVD is used.

In accordance with some embodiments, dielectric layer 32 is formed using a first precursor and a second precursor. The first precursor includes a silicon-containing precursor, which may include silane, di-silane, aminosilanes, di-sec-butylaminosilane (DSBAS), bis(tert-butylamino) silane (BTBAS), or the like, or combinations thereof. The second precursor may include other elements such as C, N, and/or O, and may be referred to as O/C/N-containing precursors hereinafter. For example, the second precursor may comprise ammonia when N is to be included in dielectric layer.

In accordance with some embodiments, dielectric layer 32B is formed using an anisotropic deposition process such as a Plasma Enhanced Atomic Layer Deposition (PEALD) process, in which plasma is generated. During the PEALD deposition process, a bias power is added. The bias power, when added, may be greater than about 150 watts, and may be in the range between about 10 watts and about 500 watts.

The plasma may be applied during and/or after the pulsing of the precursors such as the silicon-containing precursor and the O/C/N-containing precursor, and may be applied, for example, after the purging of one precursor and before the pulsing of the next precursor. For example, plasma may be turned off during the pulsing of the silicon-containing precursor, and is turned on at a time after the pulsing of the silicon-containing precursor and before the pulsing of the O/C/N-containing precursor. Similarly, plasma may be turned off during the pulsing of the O/C/N-containing precursor, and is turned on at a time after the pulsing of the O/C/N-containing precursor and before the pulsing of the silicon-containing precursor. The plasma may be generated from the purging gas such as argon, N₂, or the like.

With the using of the PEALD and the adoption of the bias power, the dielectric layer 32B is non-conformal, with the thickness T1 of the horizontal portions being greater than the thickness T2 of the vertical portions. To further enhance the anisotropic deposition effect, the process conditions of the PEALD is adjusted to ensure that the deposition is in diffusion mode. The diffusion mode may be achieved and enhanced by reducing the pulsing time (feed time), reducing purging time, and reducing the plasma treatment time. Also, the diffusion mode may be enhanced by increasing the chamber pressure during the pulsing of the precursors, and/or when the plasma is turned on.

In accordance with some embodiments, the pulsing time (feed time) of each of the precursors may be in the range between about 0.01 seconds and about 0.2 seconds. This is shorter than that of the typical non-diffusion mode deposition in which the pulsing time may be in the range between about 0.2 seconds and about 3 second. The plasma treatment time of each of the precursors may be in the range between about 0.1 seconds and about 0.3 seconds. This is shorter than that of the typical non-diffusion mode deposition in which the plasma treatment time may be in the range between about 0.3 seconds and about 2 second. The purging time of each of the precursors may be reduced to be in the range between about 0.5 seconds and about 1.5 seconds.

In accordance with alternative embodiments, dielectric layer 32B is deposited using Physical Vapor Deposition (PVD), with bias power being applied to achieve the anisotropic deposition. For example, the bias power may be in the range between about 1,000 watts and about 3,000 watts.

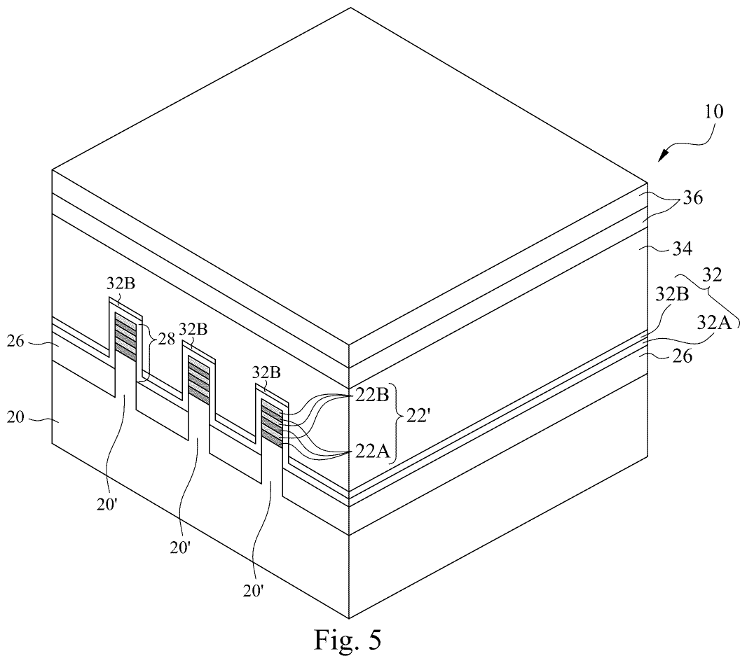

Referring to FIG. 5, dummy gate electrode layer 34 is deposited. The respective process is illustrated as process 212 in the process flow 200 as shown in FIG. 16. A planarization process is then performed to level the top surface of dummy gate electrode layer 34. Dummy gate electrode layer 34 may be formed, for example, using polysilicon or amorphous silicon, and other materials such as amorphous carbon may also be used. One (or a plurality of) hard mask layer 36 is also formed over dummy gate electrode layer 34. Hard mask layers 36 may be formed of silicon nitride, silicon oxide, silicon carbo-nitride, silicon oxy-carbo nitride, or multilayers thereof.

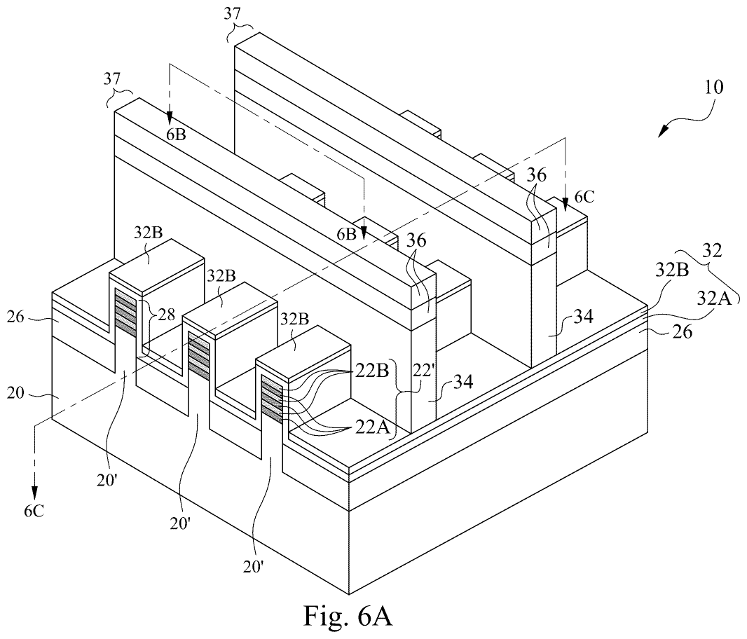

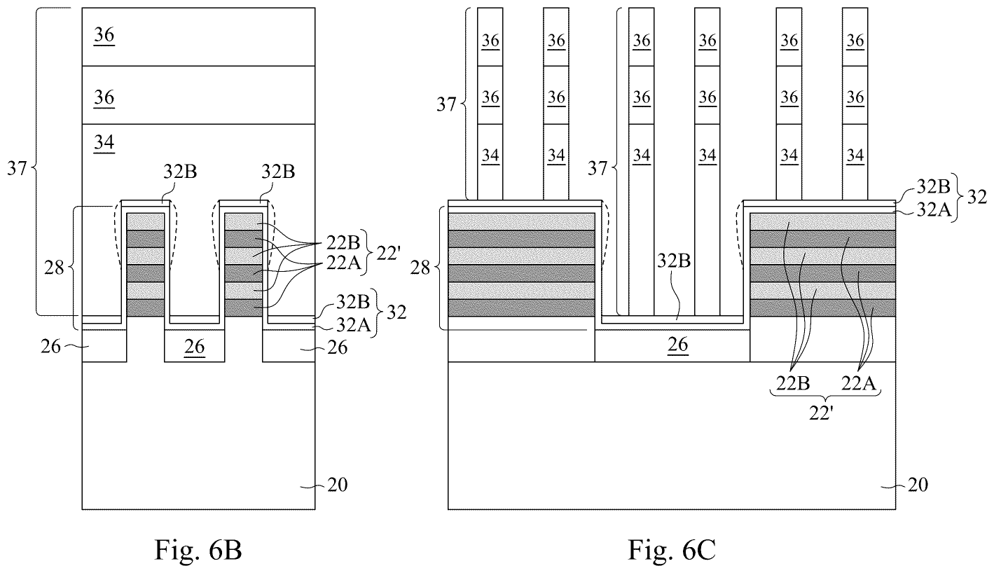

Referring to FIGS. 6A, 6B, and 6C, hard mask layer 36 and dummy gate electrode layer 34 are patterned to form dummy gate stacks 37, which include hard masks 36 and dummy gate electrodes 34. The respective process is illustrated as process 214 in the process flow 200 as shown in FIG. 16. FIGS. 6B and 6C illustrate the vertical cross-sections 6B-6B and 6C-6C, respectively, in FIG. 6A. In accordance with some embodiments, the patterning process is performed through an anisotropic etching process. The etching gas may include an oxygen containing gas such as the mixture of HBr, Cl₂, and O₂, or may include other process gases such as fluorine (F₂), Chlorine (Cl₂), hydrogen chloride (HCl), hydrogen bromide (HBr), Bromine (Br₂), C₂F₆, CF₄, SO₂, O₂, or combinations thereof. The etching is performed using dielectric layer 32B as the etch stop layer.

Subsequently, cleaning processes may be performed. The cleaning may be performed using a cleaning chemical such as diluted HF. In accordance with some embodiments, by selecting proper combination of the material of dielectric layer 32B, the chemical for the patterning of dummy gate electrode layer 34, and the cleaning chemical, the etching (loss) rate of dielectric layer 32B (during the patterning and the cleaning) is lower than the etching rate of dielectric layer 32A, which may comprise silicon oxide. For example, the etching rate ER_{32B}/ER_{32A} may be greater than about 5 or greater than about 10, wherein ER_{32B} is the etching rate of dielectric layer 32B, and ER_{32A} is the etching rate of dielectric layer 32A. As a result, the dielectric layer 32B in the embodiments of the present disclosure stops the etching better than silicon oxide, which may also be the gate oxides of IO transistors (which may be formed in the same wafer/die as the GAA transistors).

With the top portions of dielectric layer 32A being thicker and more resistance to the etching and cleaning, the possibility of the full removal of the top portion of dielectric layer 32B in the patterning process is reduced. Accordingly, the underlying top nanostructure 22B is less likely to be etched, or the loss is less if etched. The re-oxidation of the top nanostructure 22B, which is also referred to as a top sheet, is reduced, and the loss of the top sheet is reduced.

In the etching and the cleaning process, the vertical portions (FIGS. 6B and 6C) of dielectric layer 32 may also be thinned. In accordance with some embodiments, the vertical portions (if any) of dielectric layer 32B are fully removed due to their very small thickness. In accordance with alternative embodiments, the vertical portions (if formed) of dielectric layer 32B are thinned but not fully removed.

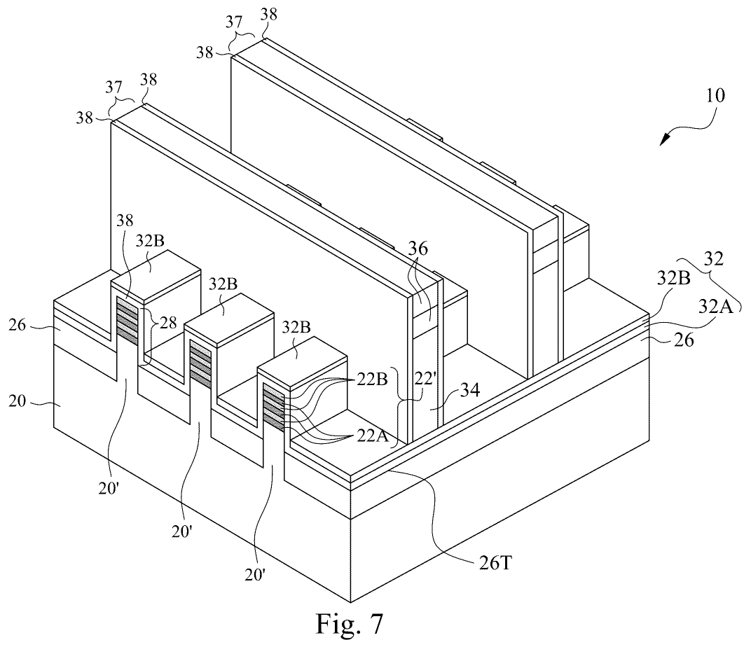

Next, as shown in FIG. 7, gate spacers 38 are formed on the sidewalls of dummy gate stacks 37. The respective process is illustrated as process 216 in the process flow 200 as shown in FIG. 16. In accordance with some embodiments, gate spacers 38 are formed of a dielectric material such as silicon nitride (SiN), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

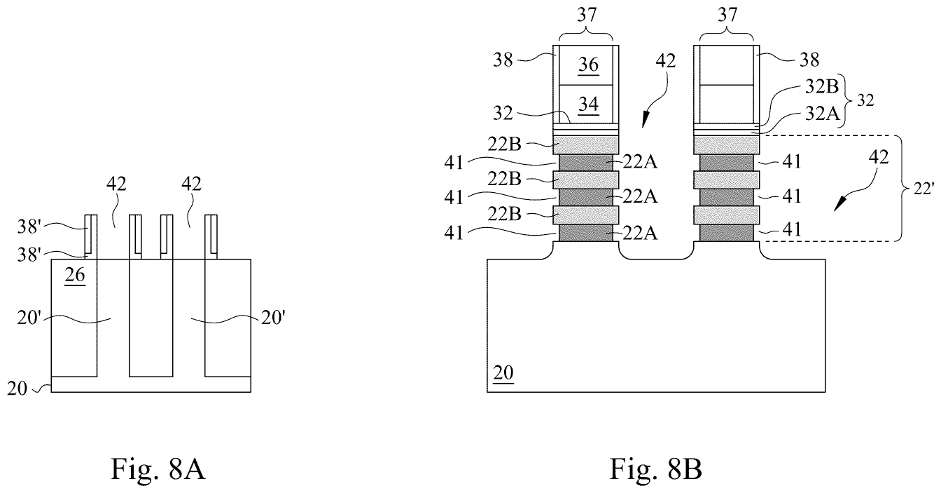

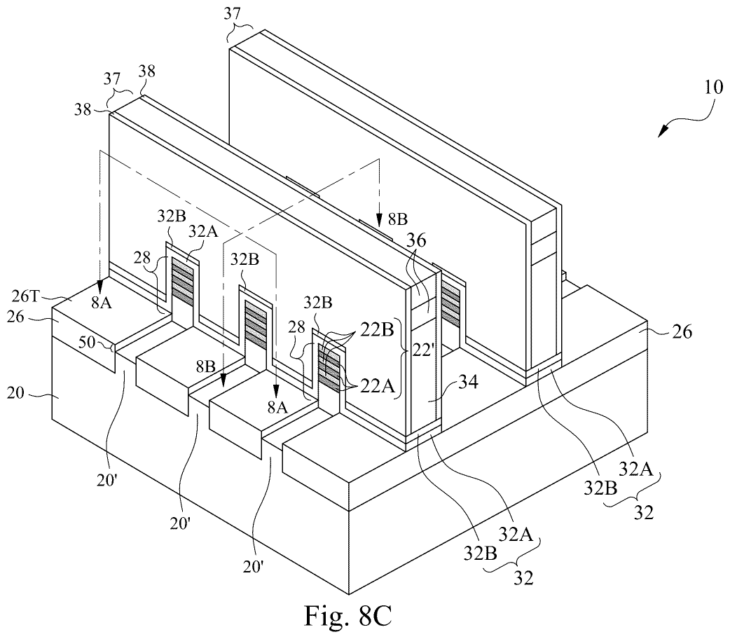

FIGS. 8A, 8B, and 8C illustrate the formation of recesses 42, from which epitaxy regions are formed. FIG. 8A illustrates the vertical cross-section 8A-8A in FIG. 8C, which cross-section passes through the portions of protruding fins 28 not covered by dummy gate stacks 37 and gate spacers. Fin spacers 38′, which are on the sidewalls of protruding fins 28, are also illustrated in FIG. 8A. FIG. 8B illustrates the reference cross-section 8B-8B in FIG. 8C, which reference cross-section is parallel to the lengthwise directions of protruding fins 28.

As shown in FIGS. 8A, 8B, and 8C, the exposed portions of dielectric layers 32 are etched. The respective process is illustrated as process 218 in the process flow 200 as shown in FIG. 16. The portions of dielectric layer 32 and protruding fins 28 that are directly underlying dummy gate stacks 37 and gate spacers 38 remain after the etching process. The respective process is illustrated as process 220 in the process flow 200 as shown in FIG. 16. The remaining portions of dielectric layer 32 are considered as parts of dummy gate stacks 37. In accordance with some embodiments, the etching process comprises a dry etch process performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than, the bottoms of multilayer semiconductor stacks 22′. The etching may be anisotropic, so that the sidewalls of multilayer semiconductor stacks 22′ facing recesses 42 are vertical and straight.

Referring to FIG. 8B, sacrificial semiconductor layers 22A are laterally recessed to form lateral recesses 41, which are recessed from the edges of the respective overlying and underlying nanostructures 22B. The respective process is illustrated as process 222 in the process flow 200 as shown in FIG. 16. The lateral recessing of sacrificial semiconductor layers 22A may be achieved through a wet etching process using an etchant that is more selective to the material (for example, silicon germanium (SiGe)) of sacrificial semiconductor layers 22A than the material (for example, silicon (Si)) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, or the like. In accordance with alternative embodiments, the lateral recessing of sacrificial semiconductor layers 22A is performed through an isotropic dry etching process or a combination of a dry etching process and a wet etching process.

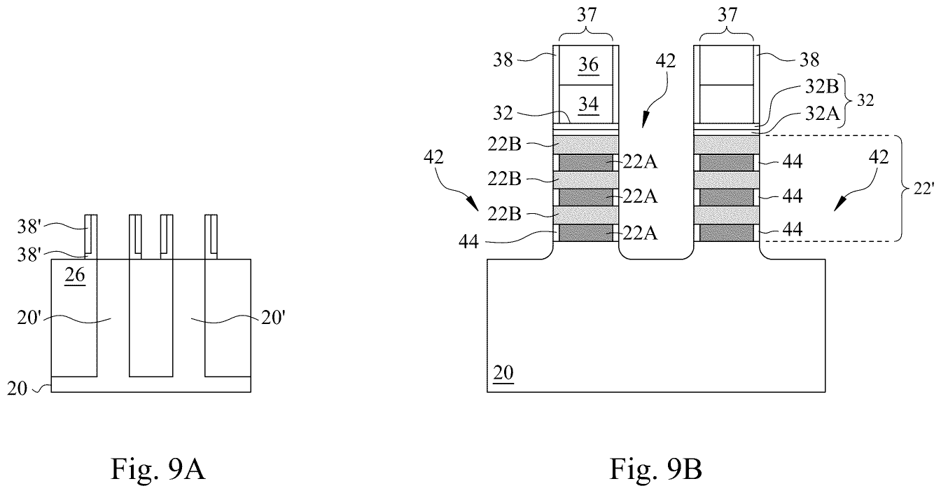

FIGS. 9A and 9B illustrate the formation of inner spacers 44. The respective process is illustrated as process 224 in the process flow 200 as shown in FIG. 16. The formation process incudes depositing a spacer layer extending into recesses 41, and performing an etching process to remove the portions of inner spacer layer outside of recesses 41, thus leaving inner spacers 44 in recesses 41. Inner spacers 44 may be formed of or comprise SiOCN, SiON, SiOC, SiCN, or the like. accordance with some embodiments, the etching of the spacer layer may be performed through a wet etching process, in which the etching chemical may include H₂SO₄, diluted HF, ammonia solution (NH₄OH, ammonia in water), or the like, or combinations thereof.

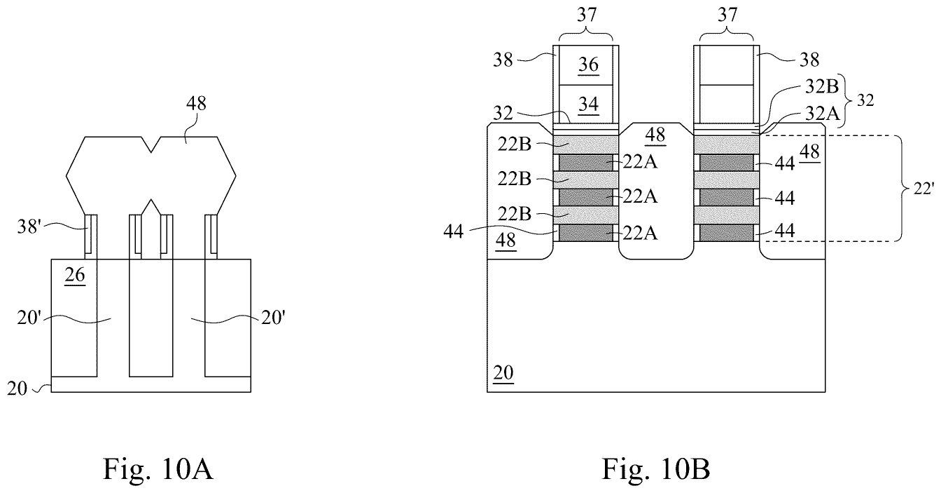

FIGS. 10A and 10B illustrate the cross-sectional views and a perspective view in the formation source/drain regions 48 in recesses 42 through epitaxy. The respective process is illustrated as process 226 in the process flow 200 as shown in FIG. 16. Source/drain region(s) may refer to a source or a drain, individually or collectively dependent upon the context. In accordance with some embodiments, the source/drain regions 48 may exert stress on the nanostructures 22B, which are used as the channels of the corresponding GAA transistors, thereby improving performance.

In accordance with some embodiments, the corresponding transistor is n-type, and epitaxial source/drain regions 48 are accordingly formed as n-type by doping an n-type dopant. For example, silicon phosphorous (SiP), silicon carbon phosphorous (SiCP), or the like may be grown to form epitaxial source/drain regions 48. In accordance with alternative embodiments, the corresponding transistor is p-type, and epitaxial source/drain regions 48 are accordingly formed as p-type by doping a p-type dopant. For example, silicon boron (SiB), silicon germanium boron (SiGeB), or the like may be grown to form epitaxial source/drain regions 48. After recesses 42 are filled with epitaxy regions 48, the further epitaxial growth of epitaxy regions 48 causes epitaxy regions 48 to expand horizontally, and facets may be formed. The further growth of epitaxy regions 48 may also cause neighboring epitaxy regions 48 to merge with each other.

After the epitaxy process, epitaxy regions 48 may be further implanted with an n-type impurity or a p-type impurity to form source and drain regions, which are also denoted using reference numeral 48. In accordance with alternative embodiments of the present disclosure, the implantation process is skipped when epitaxy regions 48 are in-situ doped with the n-type impurity or p-type impurity during the epitaxy, and the epitaxy regions 48 are also source/drain regions.

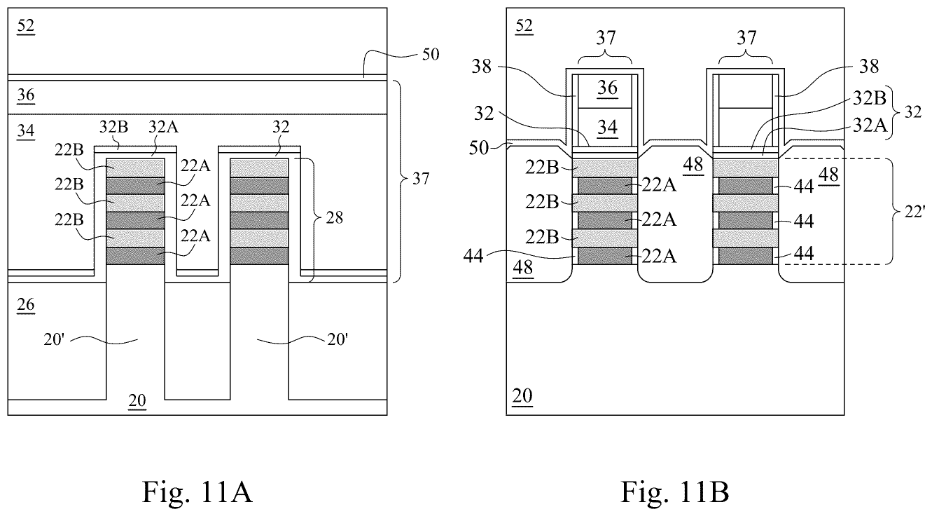

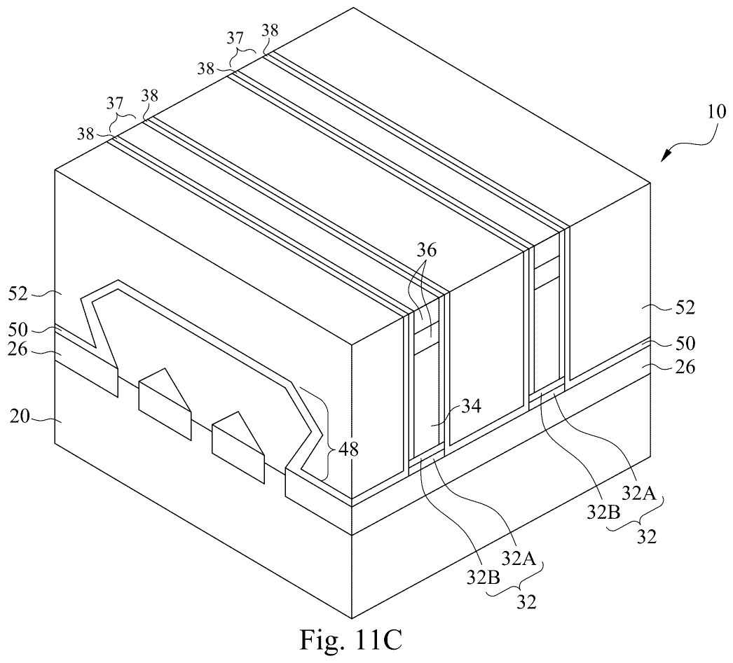

FIGS. 11A, 11B, and 11C illustrate the cross-sectional views and a perspective view of the structure after the formation of Contact Etch Stop Layer (CESL) 50 and Inter-Layer Dielectric (ILD) 52. The respective process is illustrated as process 228 in the process flow 200 as shown in FIG. 16. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be a silicon-oxide based material such as silicon oxide, Phospho-Silicate Glass (PSG), Boro-Silicate Glass (BSG), Boron-Doped Phospho-Silicate Glass (BPSG), Undoped Silicate Glass (USG), or the like.

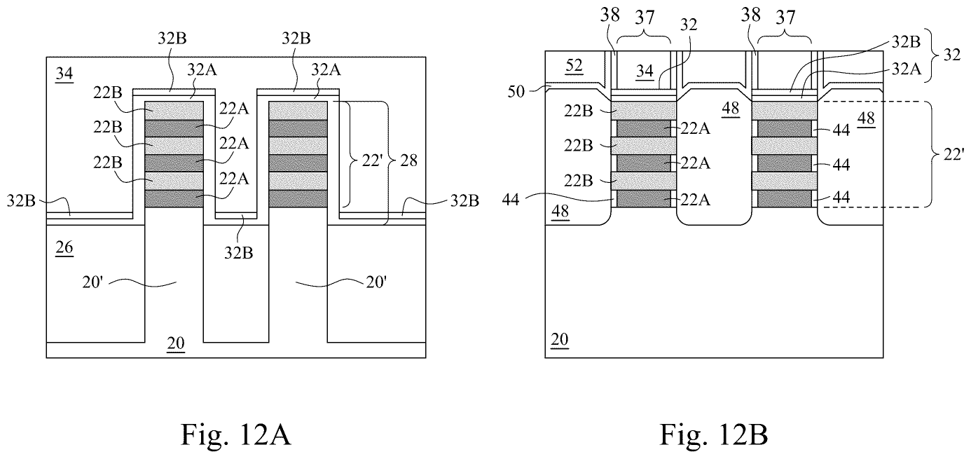

FIGS. 12A and 12B through FIGS. 15A and 15B illustrate the process for forming replacement gate stacks and contact plugs. In FIGS. 12A and 12B, a planarization process such as a CMP process or a mechanical grinding process is performed to level the top surface of ILD 52. In accordance with some embodiments, the planarization process may remove hard masks 36 to reveal dummy gate electrodes 34, as shown in FIG. 12A. The respective process is illustrated as process 230 in the process flow 200 as shown in FIG. 16. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

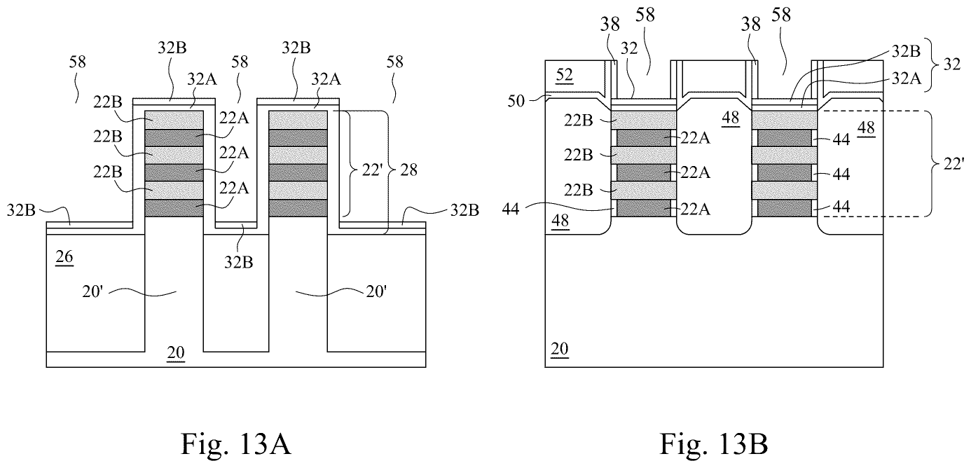

Next, in the process shown in FIGS. 13A and 13B, dummy gate electrodes 34 (and hard masks 36, if remaining) are removed in one or more etching processes, so that recesses 58 are formed. The respective process is illustrated as process 232 in the process flow 200 as shown in FIG. 16. The portions of the dielectric layer 32B in recesses 58 are exposed.

In accordance with some embodiments, the removal of dummy gate electrodes 34 may be performed through a dry and/or wet etching process. For example, when dry etching is performed, the etching gas may include F₂, Cl₂, HCl, HBr, Br₂, C₂F₆, CF₄, SO₂, or the like, or combinations thereof.

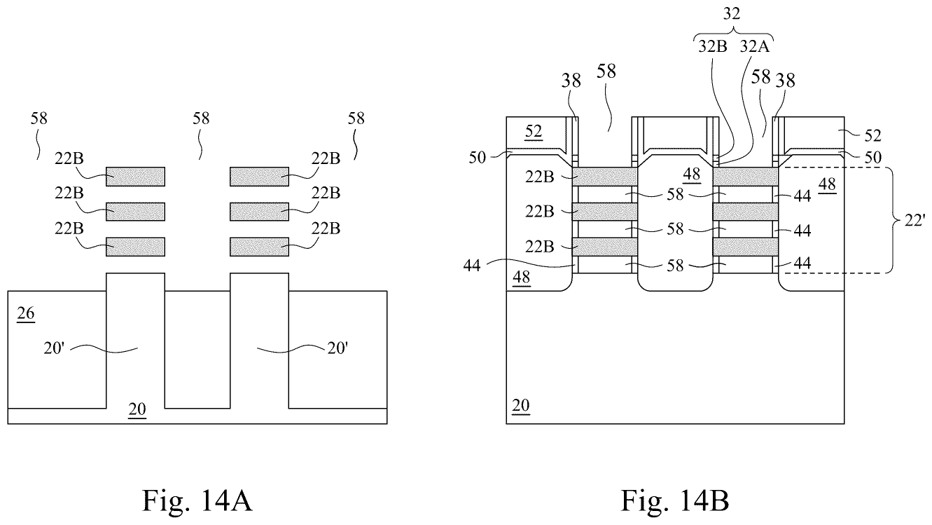

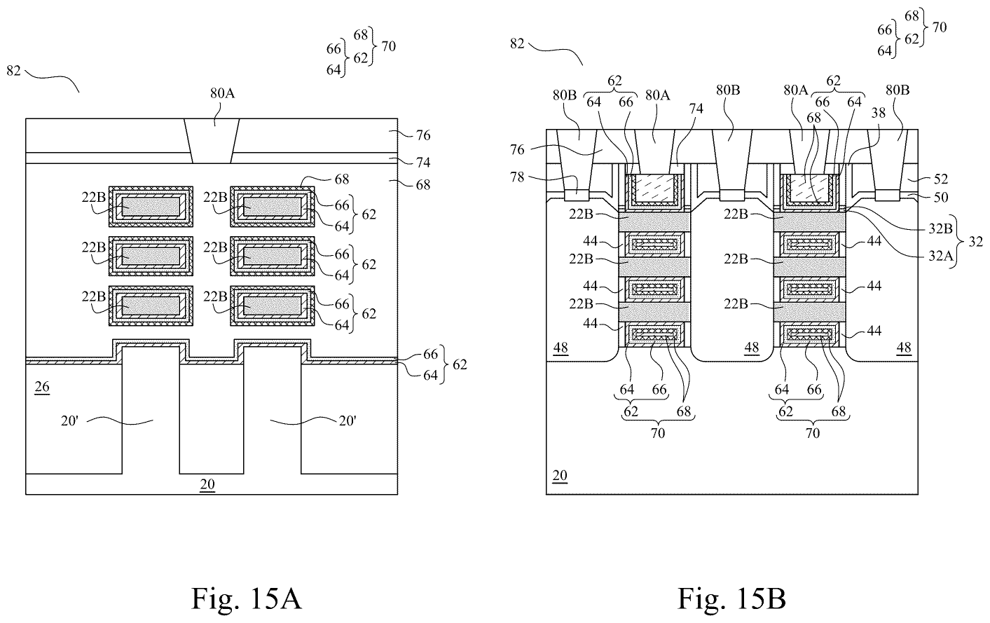

Referring to FIGS. 14A and 14B, the exposed portions of the composite gate dielectrics 32 are etched. The respective process is illustrated as process 234 in the process flow 200 as shown in FIG. 16. The portions of gate dielectrics 32 directly underlying gate spacers 38, on the other hand, are protected from being removed.

Sacrificial layers 22A are then removed to extend recesses 58 between nanostructures 22B. The respective process is illustrated as process 236 in the process flow 200 as shown in FIG. 16. Sacrificial layers 22A may be removed by performing an isotropic etching process such as a wet etching process using etchants which are selective to the materials of sacrificial layers 22A, while nanostructures 22B, substrate 20, STI regions 26, and the remaining gate dielectrics 32A are relatively un-etched as compared to sacrificial layers 22A. In accordance with some embodiments in which sacrificial layers 22A include, for example, SiGe, and nanostructures 22B include, for example, Si or carbon-doped silicon, chemicals such as tetra methyl ammonium hydroxide (TMAH), ammonium hydroxide (NH₄OH), or the like may be used to remove sacrificial layers 22A.

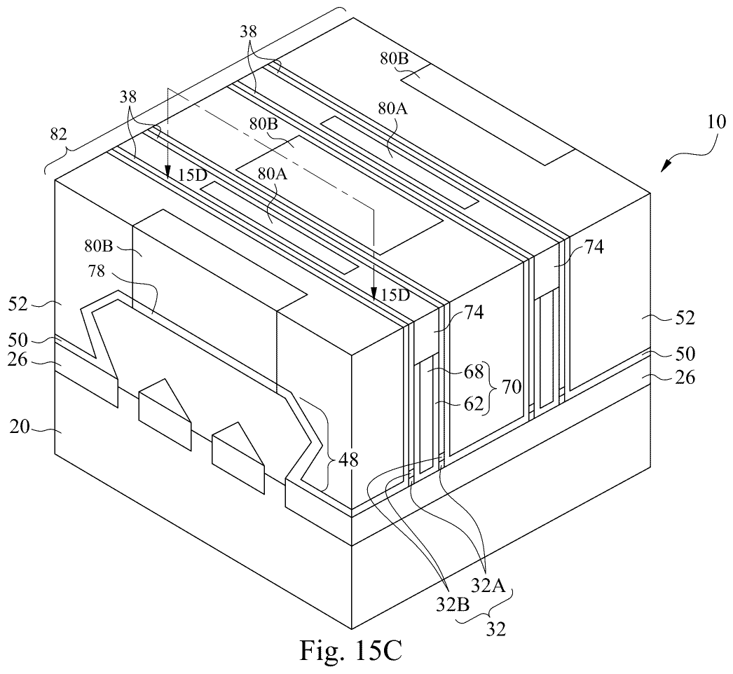

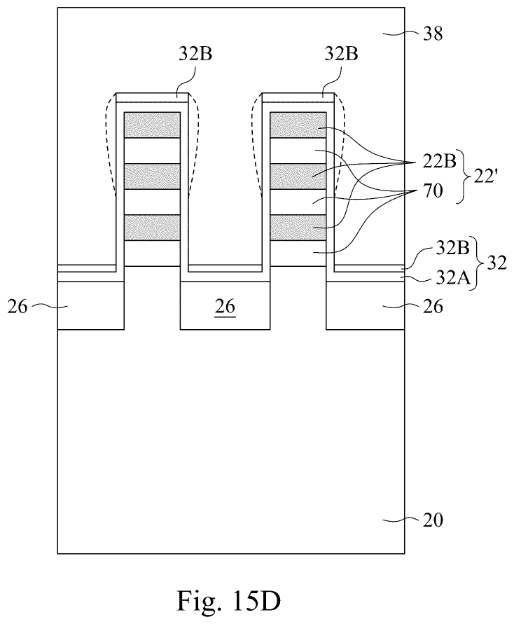

Referring to FIGS. 15A, 15B, and 15C, gate stacks 70 are formed. The respective process is illustrated as process 238 in the process flow 200 as shown in FIG. 16. Gate dielectrics 62 are first formed. In accordance with some embodiments, each of gate dielectrics 62 includes an interfacial layer 64 and a high-k dielectric layer 66 on the interfacial layer 64. The interfacial layer 64 may be formed of or comprise silicon oxide, which may be deposited through a conformal deposition process such as ALD or CVD. In accordance with some embodiments, the high-k dielectric layer 66 comprises one or more dielectric layers. For example, high-k dielectric layer 66 may include a metal oxide or a silicate of hafnium, aluminum, zirconium, lanthanum, manganese, barium, titanium, lead, and combinations thereof.

Gate electrodes 68 are formed over gate dielectrics 62. In the formation process, conductive layers are first formed on high-k dielectric layer 66 to fill the remaining portions of recesses 58. Gate electrodes 68 may include a metal-containing material such as TiN, TaN, TiAl, TiAlC, cobalt, ruthenium, aluminum, tungsten, combinations thereof, and/or multilayers thereof. Gate electrodes 68 may also comprise a filling metal such as cobalt, tungsten, or the like. Gate dielectrics 62 and gate electrodes 68 also fill the spaces between adjacent ones of nanostructures 22B, and fill the spaces between the bottom ones of nanostructures 22B and the underlying substrate strips 20′. After the filling of recesses 58, a planarization process such as a CMP process or a mechanical grinding process is performed to remove the excess portions of gate dielectrics 62 and gate electrodes 68, which excess portions are over the top surface of ILD 52. Gate electrodes 68 and gate dielectrics 62 are collectively referred to as gate stacks 70 of the resulting nano-FETs.

Next, gate stacks 70 are recessed, so that recesses are formed directly over gate stacks 70 and between opposing portions of gate spacers 38. A gate mask 74 comprising one or more layers of dielectric materials, such as silicon nitride, silicon oxynitride, or the like, is filled in each of the recesses, followed by a planarization process to remove excess portions of the dielectric material extending over ILD 52.

As further illustrated by FIGS. 15A and 15B, ILD 76 is deposited over ILD 52 and over gate masks 74. An etch stop layer (not shown), may be, or may not be, deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

ILD 76, ILD 52, CESL 50, and gate masks 74 are etched to form recesses (occupied by contact plugs 80A and 80B), through which the epitaxial source/drain regions 48 and gate stacks 70 are exposed. The recesses may be formed through an anisotropic etching process, such as RIE, NBE, or the like. Although FIG. 15B illustrates that contact plugs 80A and 80B are in a same cross-section, in various embodiments, contact plugs 80A and 80B may be formed in different cross-sections, thereby reducing the risk of shorting with each other. After the recesses are formed, silicide regions 78 are formed over the epitaxial source/drain regions 48. In accordance with some embodiments, silicide regions 78 are formed through metal deposition and anneal processes.

Gate contact plugs 80A and source/drain contact plugs 80B are formed. The respective process is illustrated as process 240 in the process flow 200 as shown in FIG. 16. Gate contacts 80A are over and contacting gate electrodes 68. Source/drain contact plugs 80B are formed over silicide regions 78. Contact plugs 80A and 80B may each comprise one or more layers, such as a barrier layer and a filling material. The barrier layer may include titanium, titanium nitride, tantalum, tantalum nitride, or the like. The filling material may include copper, a copper alloy, silver, gold, tungsten, cobalt, aluminum, nickel, and/or the like. A planarization process, such as a CMP process, may be performed to remove excess material from a surface of ILD 76. GAA transistor 82 is thus formed.

Both of dielectric layers 32A and 32B may exist in the final GAA transistor 82. A cross-section 15D-15D (FIG. 15C), which passes through gate spacer 38, is shown in FIG. 15D. Dielectric layer 32A may be a conformal layer on a protruding fin, which includes semiconductor nanostructures 22B and gate stack 70 between neighboring semiconductor nanostructures 22B. The semiconductor nanostructures 22B and the portions of gate stack 70 between neighboring semiconductor nanostructures 22B collectively form a protruding fin higher than the top surfaces of STI regions 26. Dielectric layer 32B may include a first horizontal portion over the protruding fin, and a second horizontal portion on the top surface of STI region 26.

Dielectric layer 32B may not, or may, include sidewall portions on the sidewalls of the protruding fin. When dielectric layer 32B has sidewall portions, the bottommost ends of the sidewall portions may be higher than, level with, or lower than the mid-height of the protruding fin. The sidewall portions of the dielectric layer 32B may be joined with, or may be spaced apart from, the second horizontal portions of the second dielectric layer 32B, which second horizontal portions are on the top surface of STI region 26.

Gate spacer 38 may physically contact a sidewall portion of dielectric layer 32A, and is physically spaced apart from the top portion of dielectric layer 32A by dielectric layer 32B. Alternatively, in accordance with some embodiments in which dielectric layer 32B also includes sidewall portions (with smaller thicknesses than the top portions) on all sidewall portions of the dielectric layer 32A, gate spacer 38 is fully spaced apart from dielectric layer 32A by dielectric layer 32B.

The embodiments of the present disclosure have some advantageous features. By forming a dielectric layer using an anisotropic deposition process, the dielectric layer has greater thicknesses on top of protruding fins and STI regions. In the patterning for forming dummy gates and the subsequent cleaning processes, the dielectric layer acts as a hard mask on a conformal underlying dielectric layer, so that it may reduce the top sheet loss of the semiconductor nanostructures, and reduce the loss of STI regions.

In accordance with some embodiments of the present disclosure, a method comprises forming a protruding fin; forming a first dielectric layer comprising a first top portion on a top surface of the protruding fin; and a first sidewall portion on a sidewall of the protruding fin; forming a second dielectric layer over the first top portion of the first dielectric layer and the top surface of the protruding fin, wherein the second dielectric layer is formed using an anisotropic deposition process; forming a dummy gate electrode on the second dielectric layer; forming a gate spacer on a sidewall of the dummy gate electrode; removing the dummy gate electrode; and forming a replacement gate electrode in a space left by the dummy gate electrode. In an embodiment, the second dielectric layer is free from portions on the first sidewall portion of the first dielectric layer.

In an embodiment, the first dielectric layer and the second dielectric layer are formed using different deposition methods. In an embodiment, the first dielectric layer is deposited using a conformal deposition method. In an embodiment, the second dielectric layer is deposited using plasma enhanced atomic layer deposition, with a bias power applied. In an embodiment, the method further comprises, after the dummy gate electrode is removed and before the replacement gate electrode is formed, etching exposed portions of the first dielectric layer and the second dielectric layer.

In an embodiment, after the exposed portions of the first dielectric layer and the second dielectric layer are etched, a first part of the first dielectric layer and a second part of the second dielectric layer remain directly underlying the gate spacer. In an embodiment, the second part of the second dielectric layer directly underlying the gate spacer is non-conformal. In an embodiment, the protruding fin comprises a plurality of semiconductor nanostructures stacked and spaced apart from each other, and wherein the replacement gate electrode extends into spaces between the plurality of semiconductor nanostructures.

In an embodiment, the forming the dummy gate electrode comprises depositing a polysilicon layer on the second dielectric layer, and patterning the polysilicon layer, wherein the patterning is stopped on the second dielectric layer. In an embodiment, the second dielectric layer comprises a second sidewall portion on the first sidewall portion, and wherein the second sidewall portion is removed in a cleaning process performed before the forming the gate spacer.

In accordance with some embodiments of the present disclosure, a structure comprises a dielectric isolation region; a plurality of semiconductor nanostructures aside of, and higher than, the dielectric isolation region, wherein higher ones of the plurality of semiconductor nanostructures overlap respective lower ones of the plurality of semiconductor nanostructures; a gate stack comprising a first portion over a top nanostructure of the plurality of semiconductor nanostructures; and second portions between neighboring ones of the plurality of semiconductor nanostructures, wherein the second portions of the gate stack and the plurality of semiconductor nanostructures connectively form a protruding fin; a first dielectric layer on a top surface and a sidewall of the protruding fin; a second dielectric layer comprising a first part over the first dielectric layer, wherein the second dielectric layer is less conformal than the first dielectric layer, and wherein at least a top portion of the first part is higher than a top nanostructure of the plurality of semiconductor nanostructures; and a gate spacer over the second dielectric layer.

In an embodiment, the first dielectric layer is conformal, and the first part of the second dielectric layer has a bottommost end substantially level with a topmost surface of the top nanostructure. In an embodiment, the second dielectric layer further comprises a second portion overlapping the dielectric isolation region, wherein the first portion and the second portion are discrete portions of the second dielectric layer. In an embodiment, the first portion of the second dielectric layer further comprises a second part on a sidewall of the protruding fin, wherein the second part is thinner than the first part. In an embodiment, a bottommost end of the second part is higher than a mid-height of the protruding fin.

In accordance with some embodiments of the present disclosure, a structure comprises a semiconductor substrate; a first dielectric isolation region and a second dielectric isolation region in the semiconductor substrate; a protruding fin between, and higher than, the first dielectric isolation region and the second dielectric region; a first dielectric layer on a top surface and a sidewall of the protruding fin; a second dielectric layer over the first dielectric layer, the second dielectric layer comprising a first portion overlapping the protruding fin; and a second portion overlapping the first dielectric isolation region, wherein the first portion and the second portion are discrete portions of the second dielectric layer; and a gate spacer over the second dielectric layer.

In an embodiment, the gate spacer physically contacts a sidewall part of the first dielectric layer, and is spaced apart from a top part of the first dielectric layer by the first portion of the second dielectric layer. In an embodiment, the first dielectric layer comprises silicon oxide, and the second dielectric layer comprises silicon and an element selected from the group consisting of N, C, and combinations thereof. In an embodiment, the second dielectric layer further comprises a first vertical portion on a second vertical portion of the first dielectric layer, and wherein the second vertical portion is on the sidewall of the protruding fin.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a protruding fin;
forming a first dielectric layer comprising:
a first top portion on a top surface of the protruding fin; and
a first sidewall portion on a sidewall of the protruding fin;
forming a second dielectric layer over the first top portion of the first dielectric layer and the top surface of the protruding fin, wherein the second dielectric layer is formed using an anisotropic deposition process;
forming a dummy gate electrode on the second dielectric layer;
forming a gate spacer on a sidewall of the dummy gate electrode;
removing the dummy gate electrode; and
forming a replacement gate electrode in a space left by the dummy gate electrode.

2. The method of claim 1, wherein the second dielectric layer is free from portions on the first sidewall portion of the first dielectric layer.

3. The method of claim 1, wherein the first dielectric layer and the second dielectric layer are formed using different deposition methods.

4. The method of claim 3, wherein the first dielectric layer is deposited using a conformal deposition method.

5. The method of claim 1, wherein the second dielectric layer is deposited using plasma enhanced atomic layer deposition, with a bias power applied.

6. The method of claim 1 further comprising, after the dummy gate electrode is removed and before the replacement gate electrode is formed, etching exposed portions of the first dielectric layer and the second dielectric layer.

7. The method of claim 6, wherein after the exposed portions of the first dielectric layer and the second dielectric layer are etched, a first part of the first dielectric layer and a second part of the second dielectric layer remain directly underlying the gate spacer.

8. The method of claim 7, wherein the second part of the second dielectric layer directly underlying the gate spacer is non-conformal.

9. The method of claim 1, wherein the protruding fin comprises a plurality of semiconductor nanostructures stacked and spaced apart from each other, and wherein the replacement gate electrode extends into spaces between the plurality of semiconductor nanostructures.

10. The method of claim 1, wherein the forming the dummy gate electrode comprises depositing a polysilicon layer on the second dielectric layer, and patterning the polysilicon layer, wherein the patterning is stopped on the second dielectric layer.

11. The method of claim 10, wherein the second dielectric layer comprises a second sidewall portion on the first sidewall portion, and wherein the second sidewall portion is removed in a cleaning process performed before the forming the gate spacer.

12. A structure comprising:
a dielectric isolation region;
a plurality of semiconductor nanostructures aside of, and higher than, the dielectric isolation region, wherein higher ones of the plurality of semiconductor nanostructures overlap respective lower ones of the plurality of semiconductor nanostructures;
a gate stack comprising:
a first portion over a top nanostructure of the plurality of semiconductor nanostructures; and
second portions between neighboring ones of the plurality of semiconductor nanostructures, wherein the second portions of the gate stack and the plurality of semiconductor nanostructures connectively form a protruding fin;
a first dielectric layer on a top surface and a sidewall of the protruding fin;
a second dielectric layer comprising a first part over the first dielectric layer, wherein the second dielectric layer is less conformal than the first dielectric layer, and wherein at least a top portion of the first part is higher than a top nanostructure of the plurality of semiconductor nanostructures; and
a gate spacer over the second dielectric layer.

13. The structure of claim 12, wherein the first dielectric layer is conformal, and the first part of the second dielectric layer has a bottommost end substantially level with a topmost surface of the top nanostructure.

14. The structure of claim 12, wherein the second dielectric layer further comprises a second portion overlapping the dielectric isolation region, wherein the first portion and the second portion are discrete portions of the second dielectric layer.

15. The structure of claim 12, wherein the first portion of the second dielectric layer further comprises a second part on a sidewall of the protruding fin, wherein the second part is thinner than the first part.

16. The structure of claim 15, wherein a bottommost end of the second part is higher than a mid-height of the protruding fin.

17. A structure comprising:
a semiconductor substrate;
a first dielectric isolation region and a second dielectric isolation region in the semiconductor substrate;
a protruding fin between, and higher than, the first dielectric isolation region and the second dielectric region;
a first dielectric layer on a top surface and a sidewall of the protruding fin;
a second dielectric layer over the first dielectric layer, the second dielectric layer comprising:
a first portion overlapping the protruding fin; and
a second portion overlapping the first dielectric isolation region, wherein the first portion and the second portion are discrete portions of the second dielectric layer; and
a gate spacer over the second dielectric layer.

18. The structure of claim 17, wherein the gate spacer physically contacts a sidewall part of the first dielectric layer, and is spaced apart from a top part of the first dielectric layer by the first portion of the second dielectric layer.

19. The structure of claim 17, wherein the first dielectric layer comprises silicon oxide, and the second dielectric layer comprises silicon and an element selected from the group consisting of N, C, and combinations thereof.

20. The structure of claim 17, wherein the second dielectric layer further comprises a first vertical portion on a second vertical portion of the first dielectric layer, and wherein the second vertical portion is on the sidewall of the protruding fin.
